(19) United States
(12) Patent Application Publication
(10) Pub. No.: US 2026/0273808 A1
(43) Pub. Date: Sep. 17, 2026

(54) IMPRINT APPARATUS, IMPRINT METHOD, ARTICLE MANUFACTURING METHOD, AND NON-TRANSITORY MEMORY MEDIUM STORING PROGRAM

(71) Applicant: CANON KABUSHIKI KAISHA, Tokyo (JP)

(72) Inventor: TOMOHIRO SAITO, Tochigi (JP)

(21) Appl. No.: 19/426,768

(22) Filed: Dec. 19, 2025

(30) Foreign Application Priority Data
Jan. 22, 2025 (JP) 2025-009331

(51) Int. Cl. B29C 43/58; B29C 43/18

(52) U.S. Cl. CPC B29C 43/58; B29C 43/18; B29C 2043/5833

(57) ABSTRACT

An imprint apparatus forms a pattern by bringing an imprint material on a partial field of a substrate and a pattern region of a mold into contact with each other and curing the imprint material. The imprint apparatus includes an adjuster configured to adjust a relative position between the substrate and the mold, and a controller configured to control the adjuster so as to bring the imprint material and the pattern region into contact with each other in a state in which the partial field has an offset in an inside direction of the substrate with respect to the pattern region, and then perform alignment between the pattern region and the partial field.

### BACKGROUND

### Field of the Technology

The present disclosure relates to an imprint apparatus, an imprint method, an article manufacturing method, and a non-transitory memory medium storing a program.

### Description of the Related Art

An imprint apparatus performs an imprint process of forming a pattern on a substrate by bringing the pattern region of a mold and an imprint material supplied onto a shot region of the substrate into contact with each other, and curing the imprint material. As described in Japanese Patent Laid-Open No. 2024-78506, the types of shot regions include a full field having a rectangular shape and a partial field whose shape is defined by the outer periphery of the substrate.

When forming a pattern in the partial field of a substrate by an imprint process, an imprint material or a cured product thereof having spread to the outside of the partial field may remain in the pattern region of a mold after the imprint process. If the imprint material or the cured product thereof remains in the pattern region, this can cause a defect to be generated when forming a pattern in the next shot region.

### SUMMARY

The present disclosure provides a technique advantageous in performing an imprint process on the partial field of a substrate.

The present invention provides an imprint apparatus that forms a pattern by bringing an imprint material on a partial field of a substrate and a pattern region of a mold into contact with each other and curing the imprint material, comprising: an adjuster configured to adjust a relative position between the substrate and the mold; and a controller configured to control the adjuster so as to bring the imprint material and the pattern region into contact with each other in a state in which the partial field has an offset in an inside direction of the substrate with respect to the pattern region, and then perform alignment between the pattern region and the partial field.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view schematically showing the configuration of an imprint apparatus according to an embodiment;

FIG. 2 is a flowchart illustrating the operation of the imprint apparatus according to the embodiment;

FIG. 3 is a view exemplarily showing a shot layout on a substrate;

FIGS. 4A to 4C are views for explaining an imprint process on a partial field;

FIGS. 5A to 5F are views for explaining an imprint process on a partial field;

FIGS. 6A to 6E are views for explaining an imprint process on a partial field;

FIG. 7 is a view for explaining an imprint process on a partial field; and

FIGS. 8A to 8F are views exemplarily showing an article manufacturing method.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

An imprint apparatus forms a pattern made of the cured product of an imprint material on a substrate by an imprint process. The imprint process can include a contact step of bringing the pattern region of a mold into contact with the imprint material on the substrate, a curing step of curing the imprint material, and a separation step of separating the mold from the cured product of the imprint material. Alternatively, the imprint process can also include an arrangement step of arranging the imprint material on the substrate. Through the imprint process, a pattern made of the cured product of the imprint material is formed on the substrate. The substrate includes a plurality of shot regions, and the imprint process can be executed on each shot region. The plurality of shot regions of the substrate can include a full field and a partial field.

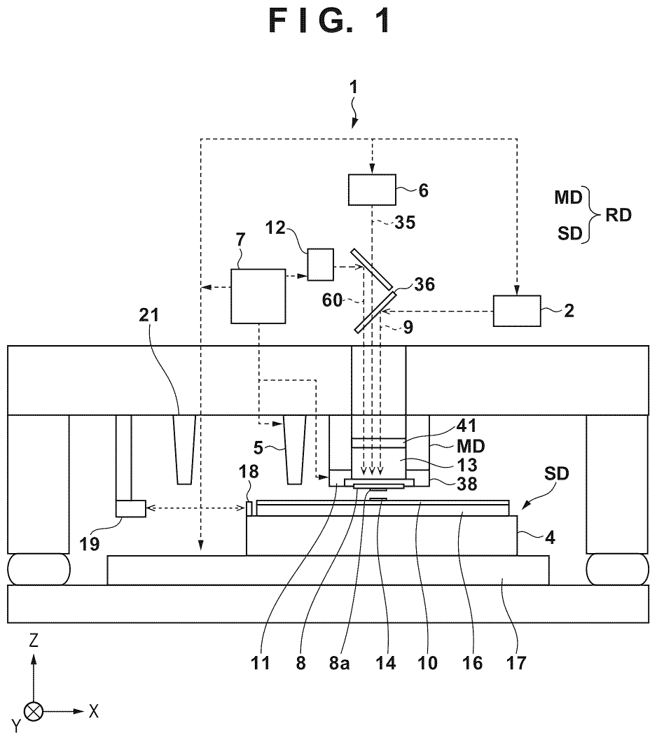

FIG. 1 schematically shows the configuration of an imprint apparatus 1. In the specification and accompanying drawings, directions will be indicated on an XYZ coordinate system in which a plane on which a substrate 10 is arranged is defined as the X-Y plane, and a direction orthogonal thereto is defined as the Z-axis direction. The imprint apparatus 1 brings a pattern region 8a of a mold 8 into contact with an imprint material 14 supplied onto the substrate 10, and applies curing energy 9 to the imprint material 14, thereby forming a cured product pattern with the pattern of the pattern region 8a transferred thereto. The mold 8 can also be called a mold, a template, or an original. The imprint apparatus 1 shown in FIG. 1 can be used to manufacture an article such as a semiconductor device.

The imprint apparatus 1 can include a mold driving mechanism MD (imprint head) that drives the mold 8, a substrate driving mechanism SD that drives the substrate 10, and a dispenser 5 that arranges the imprint material 14 on the substrate 10. The imprint apparatus 1 can also include a curing unit 2 that emits the curing energy 9 (for example, light energy) for curing the imprint material 14, and an image capturing unit 6 that captures, using light 35, an image which includes features indicating the contact state between the mold 8 and the imprint material 14. The imprint apparatus 1 can also include a detector (alignment scope) 12 that detects the relative position between the shot region of the substrate 10 and the pattern region 8a of the mold 8. The imprint apparatus 1 can also include an off-axis scope 21 that detects the arrangement of a plurality of shot regions of the substrate 10. The imprint apparatus 1 includes a controller 7 that controls a plurality of components of the imprint apparatus 1, and controls the operation of the imprint apparatus 1. The controller 7 can be constituted by, for example, a PLD (the abbreviation of Programmable Logic Device) such as an FPGA (the abbreviation of Field Programmable Gate Array), an ASIC (the abbreviation of Application Specific Integrated Circuit), a general-purpose or dedicated computer with a program installed therein, or a combination of all or some of these. The program causes the imprint apparatus 1 to execute the imprint method.

The substrate driving mechanism SD can include a substrate chuck 16 that holds the substrate 10, a substrate stage 4 that holds the substrate chuck 16, and an actuator 17 that drives the substrate stage 4. The actuator 17 can drive the substrate stage 4, for example, about at least three axes of X-, Y-, and ωz-axes, and preferably about six axes of X-, Y-, Z-, ωx-, ωy-, and ωz-axes. ωx, ωy, and ωz indicate rotations about the X-, Y-, and Z-axes, respectively. The substrate stage 4 can include, on the side surface thereof, a plurality of reference mirrors 18 corresponding to the X-, Y-, Z-, ωx-, ωy-, and ωz-axes, respectively. The imprint apparatus 1 can include a plurality of laser interferometers 19 (measuring devices) that measure the position of the substrate stage 4 by emitting beams to these reference mirrors 18, respectively. The controller 7 can control the positioning operation of the substrate 10 (substrate stage 4) based on the outputs of the laser interferometers 19. The imprint apparatus 1 may measure the position and posture of the substrate stage 4 by using an encoder instead of the reference mirrors 18 and the laser interferometers 19.

The mold driving mechanism MD can include a mold chuck 11 that holds the mold 8, and an actuator 38 that drives the mold chuck 11. The actuator 38 is configured to drive the mold chuck 11 (and the mold 8), for example, about at least three axes of the Z-, ωx-, and ωy-axes, and preferably about six axes of the X-, Y-, Z-, ωx-, ωy-, and ωz-axes. The mold driving mechanism MD may include a deformation mechanism that deforms the pattern region of the mold 8. The substrate driving mechanism SD and the mold driving mechanism MD can constitute an adjuster RD that adjusts the relative position between the substrate 10 and the mold 8.

The inverted pattern of the concave-convex pattern to be formed on the substrate 10 is formed in the pattern region 8a of the mold 8 used in the imprint apparatus 1. In the following description, a case will be described in which the pattern region 8a is provided in the mesa portion of the mold 8, but the mold 8 may not include the mesa portion. The imprint apparatus 1 forms a pattern by bringing the imprint material 14 on the shot region (full field or partial field) of the substrate 10 and the pattern region 8a of the mold 8 into contact with each other, and curing the imprint material 14. After that, the imprint apparatus 1 separates the pattern region 8a of the mold 8 from the cured product of the imprint material 14. An operation of bringing the pattern region 8a of the mold 8 into contact with the imprint material 14 on a shot region of the substrate 10, and an operation of separating the pattern region 8a of the mold 8 from the cured product of the imprint material 14 can be performed by driving the mold 8 in the Z-axis direction by the mold driving mechanism MD. However, these operations may be performed by driving the substrate 10 by the substrate driving mechanism SD, or may be performed by both the mold driving mechanism MD and the substrate driving mechanism SD.

The mold driving mechanism MD may include a light transmitting member 41 (for example, a quartz plate) that forms a sealed space 13 on the back surface side of the mold 8. By adjusting the pressure in the sealed space 13, it is possible to deform the mold 8 (pattern region 8a) into a downward convex shape when bringing the imprint material 14 and the mold 8 into contact with each other and when separating the mold 8 from the cured product of the imprint material 14.

The detector 12 can illuminate, with detection light 60, a mark formed in the mold 8 and a mark formed in the substrate 10 to capture an image formed by these marks. Based on the output of the detector 12, the imprint apparatus 1 can detect the relative position between the mold 8 (pattern region 8a) and the substrate 10 (shot region). The imprint apparatus 1 can perform alignment between the mold 8 (pattern region 8a) and the substrate 10 (shot region) by driving the adjuster RD based on the relative position.

The image capturing unit 6 is configured to fit, within the field of view, the pattern region 8a of the mold 8 held by the mold chuck 11, and can obtain an image by capturing at least one of the pattern region 8a of the mold 8 and the shot region of the substrate 10. The imprint apparatus 1 can use the image capturing unit 6 to observe the state of the imprint material 14 on the shot region of the substrate 10, and the contact state between the imprint material 14 on the shot region of the substrate 10 and the pattern region 8a of the mold 8.

The imprint material 14 is a curable composition (to be also referred to as a resin in an uncured state) to be cured by receiving curing energy. As the curing energy, an electromagnetic wave or the like can be used. The electromagnetic wave is light selected from the wavelength range of 10 nm (inclusive) to 1 mm (inclusive), for example, infrared light, a visible light beam, ultraviolet light, or the like. The curable composition is a composition cured by light irradiation or a composition cured by heating. Among these, a photo-curable composition cured by light contains at least a polymerizable compound and a photopolymerization initiator, and may contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The imprint material 14 can be arranged, on the substrate 10, in a droplet shape or in an island or film shape formed by connecting a plurality of droplets using the dispenser 5. The viscosity (the viscosity at 25° C.) of the imprint material 14 is, for example, 1 mPa·s (inclusive) to 100 mPa·s (inclusive). The imprint material 14 can include, for example, a material which can be discharged from an inkjet type liquid injection head.

The substrate 10 can include, for example, a plate-like member made of glass, a ceramic, a metal, a semiconductor, a resin, or the like. The plate-like member is, for example, a silicon wafer, a semiconductor compound wafer, or silica glass. The substrate 10 can include one or a plurality of layers on the plate-like member.

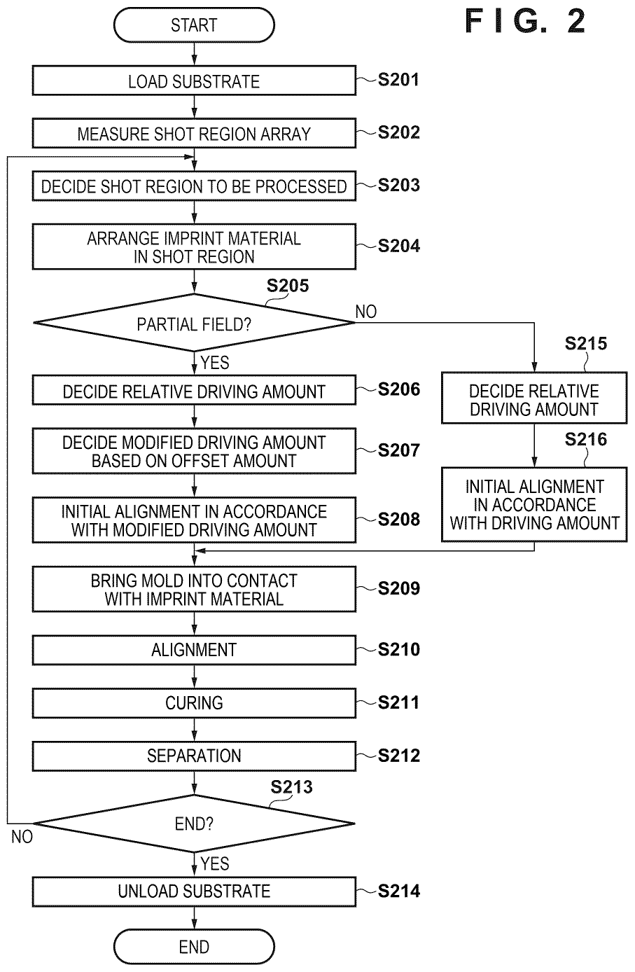

FIG. 2 exemplarily illustrates the operation of the imprint apparatus 1. In step S201, the controller 7 controls a conveyance mechanism (not shown) to convey the substrate 10 onto the substrate chuck 16. In step S202, the controller 7 uses the detector 12 and/or the off-axis scope 21 to detect the position of the mark in the substrate 10, thereby measuring the array of the plurality of shot regions of the substrate 10. In step S203, the controller 7 decides the shot region to be processed next. In step S204, the substrate driving mechanism SD and the dispenser 5 are controlled to arrange the imprint material 14 on the shot region decided in step S203. In step S205, the controller 7 determines whether the shot region to be processed next is a partial field. If the shot region to be processed next is a partial field, the controller 7 advances to step S206. On the other hand, if the shot region to be processed next is a full field, the controller 7 advances to step S215.

In step S206, the controller 7 decides the relative driving amount between the substrate 10 and the mold 8 which is required to position the shot region to be processed next, that is, the partial field below the pattern region 8a of the mold 8. This relative driving amount is the relative driving amount between the substrate 10 and the mold 8 which is required to keep the alignment error between the mold 8 (pattern region 8a thereof) and the shot region (partial field) within a tolerance. In step S207, the controller 7 decides a modified driving amount by modifying the driving amount decided in step S206 based on a predetermined offset amount. This offset amount is decided such that the imprint material 14 and the pattern region 8a can be brought into contact with each other in a state in which the partial field has an offset in the inside direction of the substrate 10 with respect to the pattern region 8a of the mold 8.

In step S208, the controller 7 performs initial alignment of relatively driving the substrate 10 and the mold 8 based on the modified driving amount decided in step S207. In other words, in step S208, the controller 7 performs initial alignment of positioning the shot region (partial field) to be processed next below the pattern region 8a of the mold 8 based on the modified driving amount. In this state, the shot region (partial field) to be processed next has an offset in the inside direction of the substrate 10 with respect to the pattern region 8a of the mold 8.

In step S215, the controller 7 decides the relative driving amount between the substrate 10 and the mold 8 which is required to position the shot region to be processed next, that is, the full field below the pattern region 8a of the mold 8. This relative driving amount is the relative driving amount between the substrate 10 and the mold 8 which is required to keep the alignment error between the mold 8 (pattern region 8a thereof) and the shot region (full field) within a tolerance. In step S216, the controller 7 performs initial alignment of relatively driving the substrate 10 and the mold 8 based on the driving amount decided in step S215. In other words, in step S216, the controller 7 performs initial alignment of positioning the shot region (full field) to be processed next below the pattern region 8a of the mold 8 based on the driving amount decided in step S215. In this state, the shot region (full field) to be processed next has no intentional offset with respect to the pattern region 8a of the mold 8.

Following step S208 or step S216, in step S209, the controller 7 controls the adjuster RD to bring the pattern region 8a of the mold 8 into contact with the imprint material 14 on the shot region. In step S210, the controller 7 controls, based on the output of the detector 12, the adjuster RD to reduce the alignment error between the shot region and the pattern region 8a, that is, to align the shot region and the pattern region 8a. Reducing the alignment error includes deforming the shot region by the deformation mechanism.

In step S211, the controller 7 controls the curing unit 2 to irradiate the imprint material 14 between the shot region and the pattern region 8a with the curing energy 9. Thus, the imprint material 14 is cured, and a pattern made of the cured product of the imprint material 14 is formed. In step S212, the controller 7 controls the adjuster RD to separate the mold 8 (pattern region 8a thereof) from the cured product of the imprint material 14 on the shot region. In step S213, the controller 7 determines whether all of the shot regions of the substrate 10 to be processed have been processed. If it is determined that all of the shot regions of the substrate 10 to be processed have been processed, in step S214, the controller 7 controls the conveyance mechanism (not shown) to convey the substrate 10 from the substrate chuck 16. On the other hand, if it is determined that there is any unprocessed shot region, the controller 7 returns to step S203, and decides the shot region to be processed next in step S203.

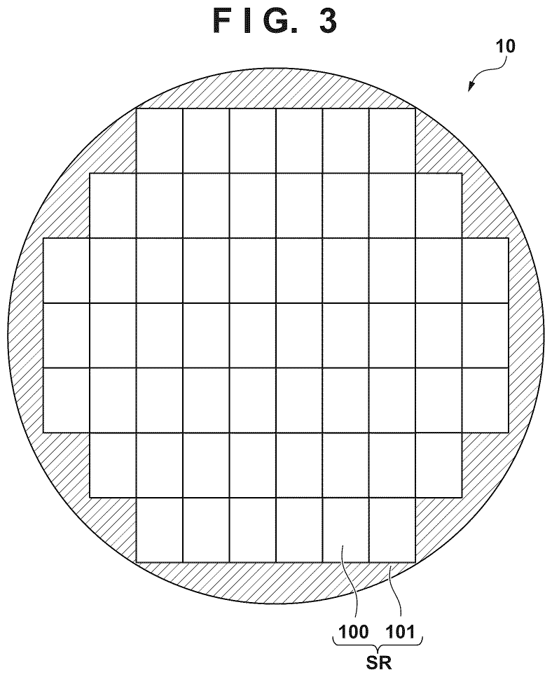

FIG. 3 exemplarily shows a shot layout on the substrate 10. The shot layout is the array of a plurality of shot regions SR on the substrate 10. The plurality of shot regions SR can include multiple full fields 100 and multiple partial fields 101. The full field 100 can have a rectangular shape. From another viewpoint, the full field 100 can have the same shape as the pattern region 8a of the mold 8. The shape of the partial field 101 is defined by the outer periphery of the substrate 10. From another viewpoint, a part of the shape of the partial field 101 is defined by an arc along the outer periphery of the substrate 10. In FIG. 3, each partial field 101 is a hatched shot region.

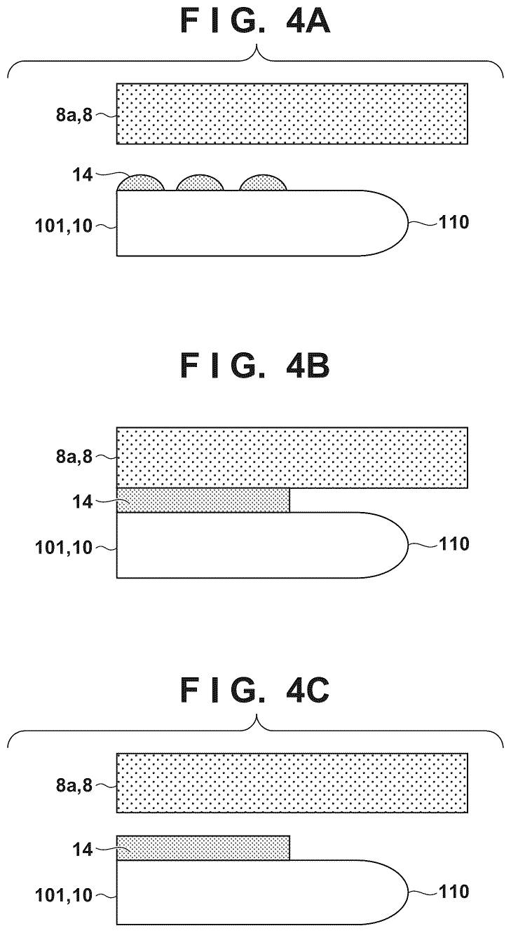

FIG. 4A schematically shows the state of the partial field 101 of the substrate 10 and the pattern region 8a of the mold 8 immediately after step S208 ends, that is, immediately after the initial alignment ends. The imprint material 14 is arranged on the partial field 101 of the substrate 10. The shortest distance between the imprint material 14 and an edge 110 of the substrate 10 can be decided based on the amount of the imprint material 14 supplied to the partial field, the distance between the substrate 10 and the pattern region 8a of the mold 8, the viscosity of the imprint material 14, the force of pressing the mold 8 against the imprint material 14, and the like. The edge 110 of the substrate 10 means the outermost periphery of the substrate 10. The outermost periphery of the effective region of the substrate 10 can exist inside the edge 110. The effective region of the substrate 10 means the region of the substrate 10 where pattern formation is allowed. The region between the outermost periphery of the effective region of the substrate 10 and the edge 110 of the substrate 10 can be a region where Edge Bead Removal (EBR) processing is performed. If the imprint material 14 protrudes to the outside of the effective region of the substrate 10, the imprint material 14 can contaminate the substrate conveyance mechanism, the substrate chuck 16, and the like.

FIG. 4B schematically shows the state of the partial field 101 and the pattern region 8a of the mold 8 immediately after step S209 ends, that is, immediately after the pattern region 8a of the mold 8 is brought into contact with the imprint material 14 on the partial field 101. When the pattern region 8a of the mold 8 comes into contact with the imprint material 14 on the partial field 101, the imprint material 14 fills the space between the partial field 101 and the pattern region 8a, thereby forming a film of the imprint material 14.

FIG. 4C schematically shows the state of the partial field 101 and the pattern region 8a of the mold 8 immediately after step S211 (curing) and step S212 (separation) end. If the relative position between the substrate 10 and the mold 8 does not change after the filling of the imprint material 14 into the space between the partial field 101 and the pattern region 8a is completed, the relative position between the edge of the imprint material 14 and the pattern region 8a of the mold 8 does not change.

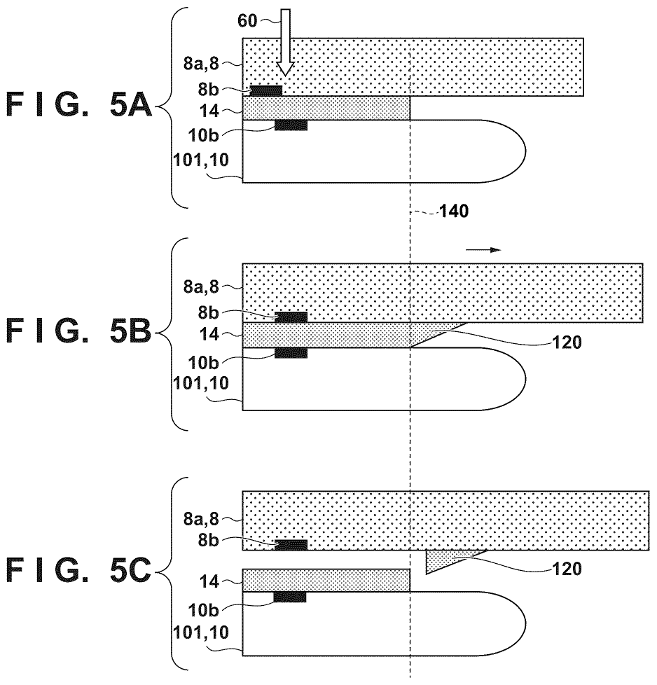

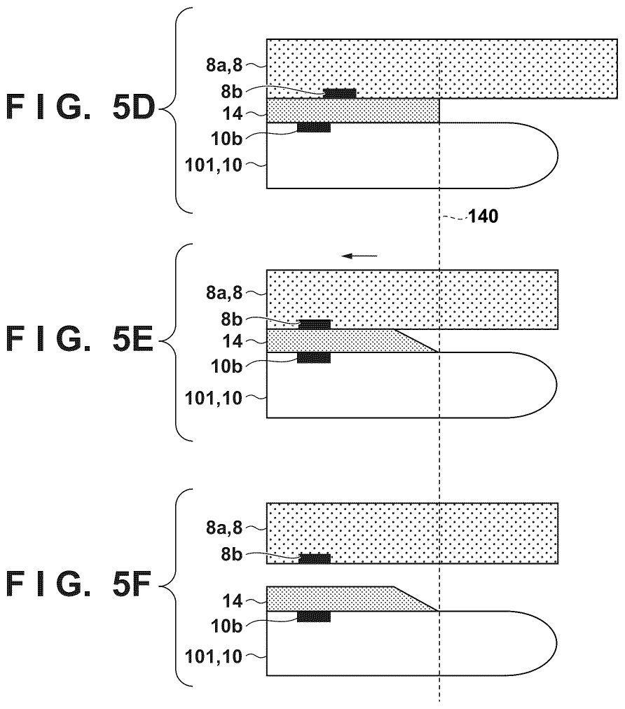

FIGS. 5A to 5C schematically show undesirable examples of initial alignment and alignment. The state in which a mark 10b provided in the partial field 101 of the substrate 10 overlaps a mark 8b provided in the pattern region 8a of the mold 8 is a state in which the alignment error between the partial field 101 and the pattern region 8a is zero. FIG. 5A schematically shows that the imprint material 14 is brought into contact with the pattern region 8a in a state in which the partial field 101 has an offset in the outside direction of the substrate 10 with respect to the pattern region 8a of the mold 8. FIG. 5B schematically shows a state in which alignment is performed to overlap the mark 10b and the mark 8b, that is, a state in which the pattern region 8a of the mold 8 is moved in the outside direction of the substrate 10 with respect to the partial field 101 (substrate 10). With this, the contact region between the pattern region 8a and the imprint material 14 increases outward in the pattern region 8a, and a protrusion portion 120 where the imprint material 14 protrudes in the outside direction of the partial field 101 can be generated. The protrusion portion 120 can be formed by the imprint material protruding to a region of the pattern region 8a not facing the partial field 101.

FIG. 5C schematically shows a state in which, after the imprint material 14 is cured in the state shown in FIG. 5B, the mold 8 is separated from the cured product of the imprint material 14 on the partial field 101 (substrate 10). In the state shown in FIG. 5B, the protrusion portion 120 is in contact with the pattern region 8a of the mold 8 but not in contact with the partial field 101 of the substrate 10. If the imprint material 14 is cured in this state and the mold 8 is separated from the cured product of the imprint material 14 on the partial field 101 (substrate 10), the imprint material 14 or the cured product thereof can remain in the pattern region 8a of the mold 8. If a process on another shot region is performed while the imprint material 14 or the cured product thereof remains in the pattern region 8a of the mold 8, a pattern with a defect can be formed on the other shot region.

FIGS. 5D to 5F schematically show initial alignment and alignment according to this embodiment. The state in which the mark 10b provided in the partial field 101 of the substrate 10 overlaps the mark 8b provided in the pattern region 8a of the mold 8 is a state in which the alignment error between the partial field 101 and the pattern region 8a is zero. FIG. 5D schematically shows that the imprint material 14 is brought into contact with the pattern region 8a in a state in which the partial field 101 has an offset in the inside direction of the substrate 10 with respect to the pattern region 8a of the mold 8. FIG. 5E schematically shows a state in which alignment is performed to overlap the mark 10b and the mark 8b, that is, a state in which the pattern region 8a of the mold 8 is moved in the inside direction of the substrate 10 with respect to the partial field 101 (substrate 10). With this, the contact region between the pattern region 8a and the imprint material 14 decreases in the inside direction of the pattern region 8a, and becomes smaller than the contact region between the partial field 101 and the imprint material 14. In this case, the protrusion portion 120 where the imprint material 14 protrudes in the outside direction of the partial field 101 is not generated. That is, according to this embodiment, the protrusion portion 120 formed by the imprint material protruding to a region of the pattern region 8a not facing the partial field 101 is not generated.

FIG. 5F schematically shows a state in which, after the imprint material 14 is cured in the state shown in FIG. 5E, the mold 8 is separated from the cured product of the imprint material 14 on the partial field 101 (substrate 10). In the state shown in FIG. 5E, the protrusion portion 120 is not formed. Therefore, even if the imprint material 14 is cured in this state and the mold 8 is separated from the cured product of the imprint material 14 on the partial field 101 (substrate 10), the imprint material 14 or the cured product thereof does not remain in the pattern region 8a of the mold 8.

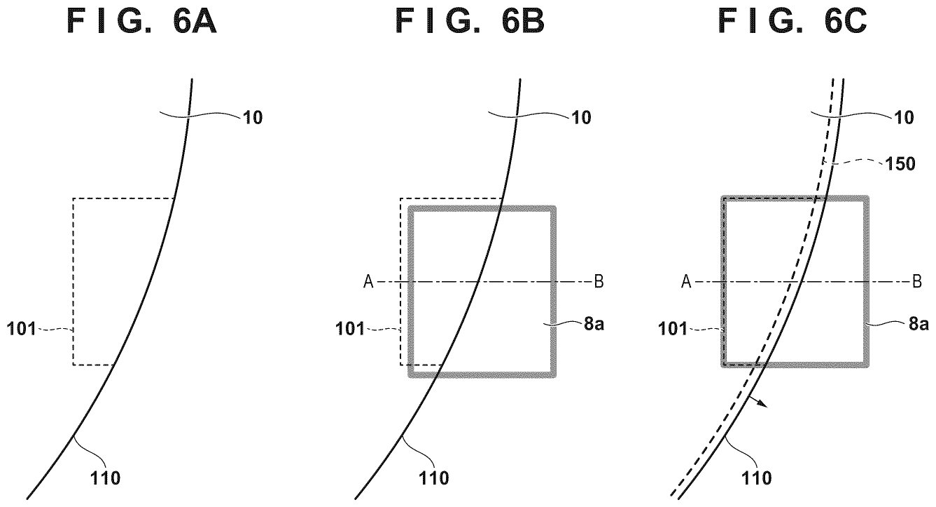

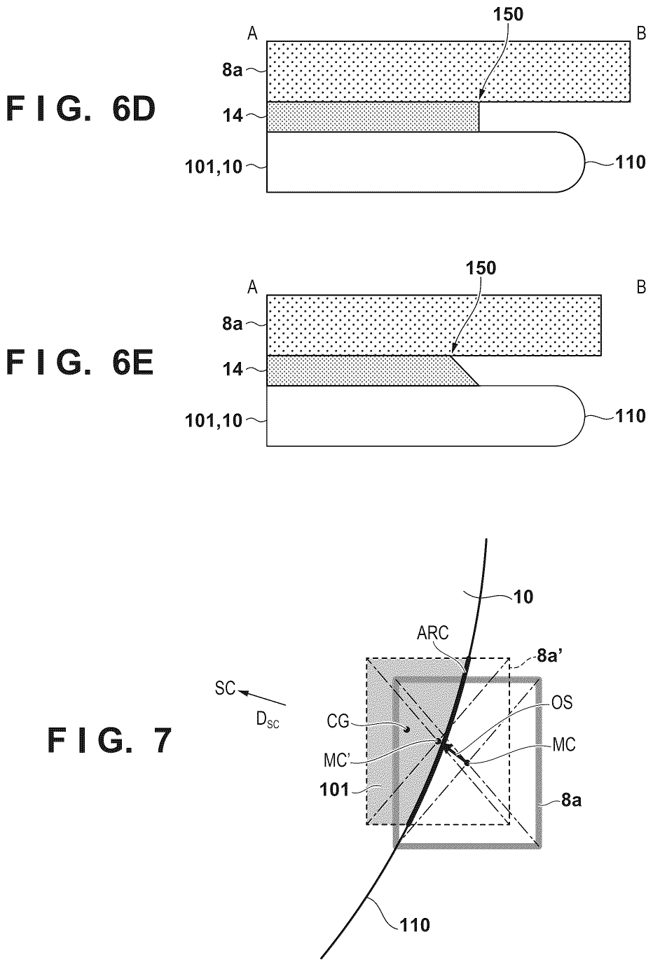

With reference to FIGS. 6A to 6E, the process according to this embodiment will further be described. FIG. 6A is a top view showing an example of the partial field 101 of the substrate 10. FIG. 6B is a top view schematically showing that the imprint material 14 is brought into contact with the pattern region 8a in a state in which the partial field 101 has an offset in the inside direction of the substrate 10 with respect to the pattern region 8a of the mold 8. FIG. 6D shows a sectional view taken along a line A-B in FIG. 6B. FIG. 6C is a top view schematically showing a state in which, after the pattern region 8a of the mold 8 is brought into contact with the imprint material 14 on the partial field 101, alignment between the partial field 101 and the pattern region 8a is performed. FIG. 6E shows a sectional view taken along a line A-B in FIG. 6C.

As schematically shown in FIGS. 6B and 6D, in the contact step, the imprint material 14 is brought into contact with the pattern region 8a in a state in which the partial field 101 has an offset in the inside direction of the substrate 10 with respect to the pattern region 8a of the mold 8. Thereafter, as schematically shown in FIGS. 6C and 6E, alignment between the pattern region 8a of the mold 8 and the partial field 101 (substrate 10) (that is, an operation to reduce the alignment error) is performed. Alignment between the pattern region 8a and the partial field 101 is performed such that the pattern region 8a of the mold 8 is moved in the inside direction of the substrate 10 with respect to the partial field 101 (substrate 10). In other words, alignment between the pattern region 8a and the partial field 101 is performed such that an edge 150 of the contact region between the pattern region 8a of the mold 8 and the imprint material 14 is moved in the inside direction of the substrate 10 with respect to the edge 110 of the substrate 10.

In the alignment between the pattern region 8a and the partial field 101, the controller 7 reduces the alignment error between the pattern region 8a and the partial field 101. Alternatively, in the alignment between the pattern region 8a and the partial field 101, the controller 7 does not increase the contact region between the pattern region 8a and the imprint material 14. Alternatively, in the alignment between the pattern region 8a and the partial field 101, the controller 7 decreases the contact region between the pattern region 8a and the imprint material 14.

Here, with reference to FIG. 7, a method of deciding the initial offset used in step S207 will exemplarily be described. Assume that a center MC of the pattern region 8a of the mold 8 is indicated by coordinates MC(X₁, Y₁). Assume also that the center of the pattern region 8a (shown as a pattern region 8a′) when the pattern region 8a is superimposed on the partial field 101 without an alignment error is defined as a virtual center MC′ and indicated by coordinates MC′(X₂, Y₂).

In the first deciding method, the controller 7 decides an offset OS of the partial field 101 with respect to the pattern region 8a in a direction from the center MC(X₁, Y₁) of the pattern region 8a toward the virtual center MC′(X₂, Y₂).

In the second deciding method, the controller 7 decides the offset OS of the partial field 101 with respect to the pattern region 8a in a direction D_{SC} from the center MC(X₁, Y₁) of the pattern region 8a toward a center SC of the substrate 10.

In the third deciding method, the controller 7 decides the offset OS of the partial field 101 with respect to the pattern region 8a in the direction D_{SC} from a barycenter CG of the partial field 101 toward the center SC of the substrate 10.

In the fourth deciding method, the controller 7 decides the offset OS of the partial field 101 with respect to the pattern region 8a in a direction from an arbitrary position on an arc ARC, which forms a part of the shape of the partial field 101, toward the center SC of the substrate 10.

In the fifth deciding method, the controller 7 decides the offset OS of the partial field 101 with respect to the pattern region 8a in a direction from the center (the position bisecting the arc ARC) of the arc ARC, which forms a part of the shape of the partial field 101, toward the center SC of the substrate 10.

The amount OSM of the offset OS can be expressed by, for example:

$$OSM = {( {( {X}_{2} - {X}_{1} )}^{2} + {( {Y}_{2} - {Y}_{1} )}^{2} )}^{1 / 2}$$

The maximum value of the amount OSM of the offset OS is set to be equal to or smaller than the maximum value with which the detector 12 can detect the alignment error between the pattern region 8a and the partial field 101. For example, the maximum value of the offset amount OSM of offset OS may be set to 2 μm or less, and is preferably set to 1 μm or less. The minimum value of the offset amount OSM of the offset OS can be decided so as to ensure that the pattern region 8a is not moved in the outside direction of the substrate 10 with respect to the partial field 101 in the alignment after the contact step. The minimum value of the offset amount OSM of the offset OS may be set to 50 nm or more, and is preferably set to 100 nm or more.

In the alignment after the contact step, it is preferable that the pattern region 8a is not moved in the outside direction of the substrate 10 with respect to the partial field 101. However, if Δ1>Δ2 is satisfied, an appropriate effect is obtained in preventing the imprint material 14 or the cured product thereof from remaining in the pattern region 8a. Here, Δ1 indicates the amount by which the pattern region 8a is initially moved in the inside direction of the substrate 10 with respect to the partial field 101 in the alignment after the contact step. Δ2 indicates the amount by which the pattern region 8a is moved in the outside direction of the substrate 10 with respect to the partial field 101 after moving by the amount Δ1. That is, it is sufficient that an edge 140 of the contact region between the pattern region 8a and the imprint material 14 does not lead to an increase in the pattern region 8a after the contact step.

The pattern of a cured product formed using an imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM, and semiconductor elements such as an LSI, a CCD, an image sensor, and an FPGA. Examples of the mold are an imprint mold and the like.

The pattern of the cured product is directly used as at least some of the constituent members of the above-described articles or used temporarily as a resist mask. After etching or ion implantation is performed in the substrate processing step, the resist mask is removed.

Next, an article manufacturing method of manufacturing an article using the imprint apparatus 1 or the above-described imprint method will be described. Roughly, the article manufacturing method can include a pattern formation step of forming a pattern on a substrate using the imprint apparatus 1 or the above-described imprint method, and a processing step of processing the substrate having undergone the pattern formation step to obtain an article.

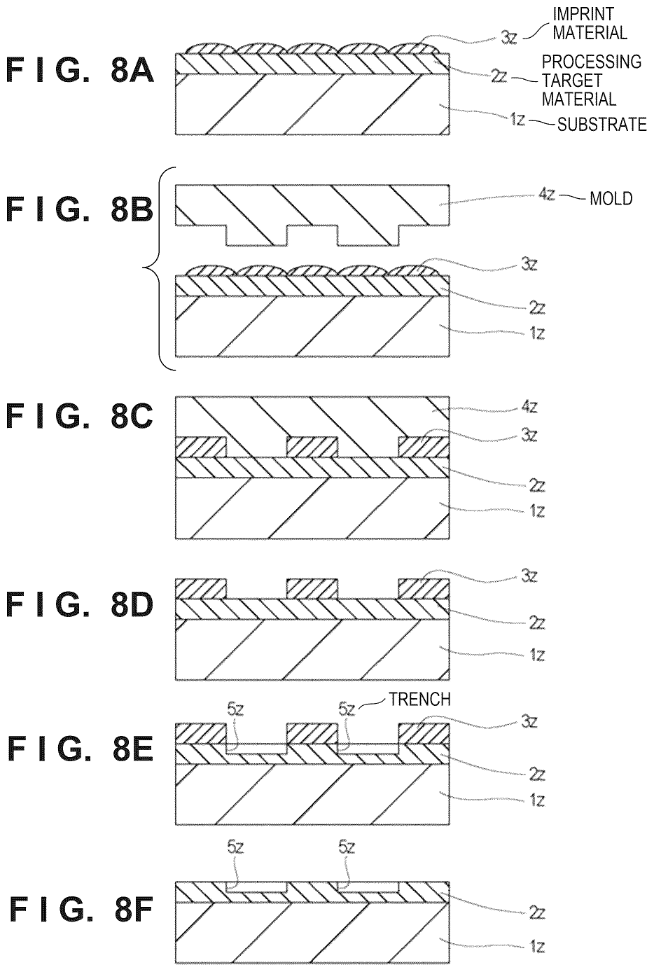

As shown in FIG. 8A, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in FIG. 8B, a side of a mold 4z for imprint with a concave-convex pattern is directed toward and made to face the imprint material 3z on the substrate. As shown in FIG. 8C, the substrate 1z to which the imprint material 3z is applied is brought into contact with the mold 4z, and a pressure is applied. The gap between the mold 4z and the processed material 2z is filled with the imprint material 3z. In this state, when the imprint material 3z is irradiated with light as energy for curing via the mold 4z, the imprint material 3z is cured.

As shown in FIG. 8D, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the concave-convex pattern of the mold 4z is transferred to the imprint material 3z.

As shown in FIG. 8E, when etching is performed using the pattern of the cured product as an etching resistant mask, a portion of the surface of the processed material 2z where the cured product does not exist or remains thin is removed to form a groove 5z. As shown in FIG. 8F, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-009331, filed Jan. 22, 2025, which is hereby incorporated by reference herein in its entirety.

What is claimed is:

1. An imprint apparatus that forms a pattern by bringing an imprint material on a partial field of a substrate and a pattern region of a mold into contact with each other and curing the imprint material, comprising:
an adjuster configured to adjust a relative position between the substrate and the mold; and
a controller configured to control the adjuster so as to bring the imprint material and the pattern region into contact with each other in a state in which the partial field has an offset in an inside direction of the substrate with respect to the pattern region, and then perform alignment between the pattern region and the partial field.

2. The apparatus according to claim 1, wherein
in the alignment, the controller reduces an alignment error between the pattern region and the partial field.

3. The apparatus according to claim 1, wherein
in the alignment, the controller does not increase a contact region between the pattern region and the imprint material.

4. The apparatus according to claim 1, wherein
in the alignment, the controller decreases a contact region between the pattern region and the imprint material.

5. The apparatus according to claim 1, wherein
assuming that a center of the pattern region when the pattern region is superimposed on the partial field without an alignment error is defined as a virtual center,
the controller brings the imprint material and the pattern region into contact with each other in a state in which the partial field has the offset with respect to the pattern region in a direction from a center of the pattern region toward the virtual center.

6. The apparatus according to claim 1, wherein
the controller brings the imprint material and the pattern region into contact with each other in a state in which the partial field has the offset with respect to the pattern region in a direction from a center of the pattern region toward a center of the substrate.

7. The apparatus according to claim 1, wherein
the controller brings the imprint material and the pattern region into contact with each other in a state in which the partial field has the offset with respect to the pattern region in a direction from a barycenter of the partial field toward a center of the substrate.

8. The apparatus according to claim 1, wherein
a part of a shape of the partial field is formed by an arc, and
the controller brings the imprint material and the pattern region into contact with each other in a state in which the partial field has the offset with respect to the pattern region in a direction from an arbitrary position on the arc toward a center of the substrate.

9. The apparatus according to claim 1, wherein
a part of a shape of the partial field is formed by an arc, and
the controller brings the imprint material and the pattern region into contact with each other in a state in which the partial field has the offset with respect to the pattern region in a direction from a center of the arc toward a center of the substrate.

10. The apparatus according to claim 1, wherein
in the alignment, the controller makes a contact region between the pattern region and the imprint material smaller than a contact region between the partial field and the imprint material.

11. The apparatus according to claim 1, wherein
the controller decides, based on a position of the partial field, a relative driving amount between the substrate and the mold which is required to keep an alignment error between the mold and the partial field within a tolerance, and decides a modified driving amount by modifying the driving amount based on a predetermined offset amount, and
before bringing the imprint material and the pattern region into contact with each other, the controller controls the adjuster to adjust a relative position between the mold and the partial field based on the modified driving amount.

12. An imprint method of forming a pattern by bringing an imprint material on a partial field of a substrate and a pattern region of a mold into contact with each other and curing the imprint material, comprising:
bringing the imprint material and the pattern region into contact with each other in a state in which the partial field has an offset in an inside direction of the substrate with respect to the pattern region; and
aligning the pattern region and the partial field after the bringing.

13. The method according to claim 12, wherein
the aligning is executed so as to reduce an alignment error between the pattern region and the partial field.

14. The method according to claim 12, wherein
the aligning is executed so as not to increase a contact region between the pattern region and the imprint material.

15. The method according to claim 12, wherein
the aligning is executed so as to decrease a contact region between the pattern region and the imprint material.

16. The method according to claim 12, wherein
assuming that a center of the pattern region when the pattern region is superimposed on the partial field without an alignment error is defined as a virtual center,
in the bringing, the imprint material and the pattern region are brought into contact with each other in a state in which the partial field has the offset with respect to the pattern region in a direction from a center of the pattern region toward the virtual center.

17. The method according to claim 12, wherein
in the bringing, the imprint material and the pattern region are brought into contact with each other in a state in which the partial field has the offset with respect to the pattern region in a direction from a center of the pattern region toward a center of the substrate.

18. The method according to claim 12, wherein
in the bringing, the imprint material and the pattern region are brought into contact with each other in a state in which the partial field has the offset with respect to the pattern region in a direction from a barycenter of the partial field toward a center of the substrate.

19. The method according to claim 12, wherein
a part of a shape of the partial field is formed by an arc, and
in the bringing, the imprint material and the pattern region are brought into contact with each other in a state in which the partial field has the offset with respect to the pattern region in a direction from an arbitrary position on the arc toward a center of the substrate.

20. The method according to claim 12, wherein
a part of a shape of the partial field is formed by an arc, and
in the bringing, the imprint material and the pattern region are brought into contact with each other in a state in which the partial field has the offset with respect to the pattern region in a direction from a center of the arc toward a center of the substrate.

21. The method according to claim 12, wherein
the aligning is executed so as to make a contact region between the pattern region and the imprint material smaller than a contact region between the partial field and the imprint material.

22. An imprint method according to claim 12, further comprising:
deciding, based on a position of the partial field, a relative driving amount between the substrate and the mold which is required to keep an alignment error between the mold and the partial field within a tolerance, and deciding a modified driving amount by modifying the driving amount based on the offset; and
adjusting a relative position between the mold and the partial field based on the modified driving amount,
wherein the bringing is executed after the adjusting.

23. An article manufacturing method comprising;
forming a pattern by bringing an imprint material on a partial field of a substrate and a pattern region of a mold into contact with each other in a state in which the partial field has an offset in an inside direction of the substrate with respect to the pattern region, aligning the pattern region and the partial field after the bringing, and curing the imprint material; and
obtaining an article by processing the substrate having undergone the forming.

24. A non-transitory memory medium storing a program for causing an imprint apparatus to execute an imprint method defined in claim 12.
